(19) United States
(12) Patent Application Publication
(10) Pub. No.: US 2022/0200248 A1
(43) Pub. Date: Jun. 23, 2022

(54) SWITCHGEAR CABINET CONFIGURATION SYSTEM

(71) Applicant: RITTAL GMBH & CO. KG, Herborn (DE)

(72) Inventors: Lars MARTIN, Münzenberg (DE); Thomas WEICHSEL, Erkelenz (DE)

(21) Appl. No.: 17/599,063

(22) PCT Filed: Mar. 27, 2020
(86) PCT No.: PCT/EP2020/058722

§ 371 Date: Sep. 28, 2021

(30) Foreign Application Priority Data
Mar. 29, 2019 (EP) 19166275.8

(51) Int. Cl. H02B 1/32; H02B 3/00

(52) U.S. Cl. CPC H02B 1/32; H02B 3/00

(57) ABSTRACT

A computer-aided switchgear cabinet configuration system, set up for configuring a switchgear cabinet which comprises a modular switchgear cabinet equipment which is composed in an application-specific manner of a plurality of electrical and/or electronic built-in modules and further optional components, having a computing unit with a classification device and an evaluation and simulation unit for generating a bundle of different switchgear cabinet concepts with in each case different layouts, a subsequent selection of a specific layout and a corresponding control of a switchgear cabinet production line.

### CROSS-REFERENCE TO RELATED APPLICATIONS

This application is a U.S. National Phase Application under 35 U.S.C. 371 of International Application No. PCT/EP2020/058722, filed on Mar. 27, 2020, which claims priority to European Patent Application No. 19,166,275.8, filed Mar. 29, 2019. The entire disclosures of the above applications are incorporated herein by reference in their entirety.

### BACKGROUND

This section provides background information related to the present disclosure which is not necessarily prior art.

### TECHNICAL FIELD

The present invention relates to a computer-aided switchgear cabinet configuration system, set up for configuring a switchgear cabinet which comprises a modular switchgear cabinet equipment which is composed, in an application-specific manner, of a plurality of electrical and/or electronic built-in modules and further optional components. Furthermore, the invention relates to a switchgear cabinet manufacturing system, a use, a method and a computer program product.

### DISCUSSION

The field of application of the invention extends to switchgear and control cabinet construction. Switchgear cabinets are primarily used in the context of industrial applications. A switchgear cabinet houses the electrical and electronic components which are designed in the form of standardized built-in modules in order to control an automated production plant, a process engineering plant, a machine tool or the like. The built-in modules housed in the switchgear cabinet are usually control components that are not arranged as field devices directly on the machine. For example, programmable logic controllers, universal computing units, frequency converters for speed control, communication modules for bus connections to various bus systems, digital input/output modules or analog input modules are used as built-in modules. In addition, a switchgear cabinet usually also contains electrical terminal strips for connecting the electrical cabling at the place of use, which establishes the connection to the power supply and the machines and systems to be controlled. The production of a switchgear cabinet with the application-specific switchgear cabinet equipment is carried out according to a three-dimensional layout previously developed in the concept stage, which also includes the parts list information of the components to be installed.

WO 2008/071309 A1 shows a switchgear cabinet arrangement with several individual switchgear cabinets, which are divided by means of wall sections into several partial compartments serving as functional compartments, in which, for example, low-voltage systems, slide-in units, cooling units and other components can be placed. In this context, a subspace can accommodate, for example, an electrical distribution rail arrangement and device adapters placed thereon for mounting associated electrical or electronic installation modules.

EP 0 943 165 B1 discloses various equipment concepts of switchgear cabinets. In a first embodiment, a component-oriented switchgear cabinet comprises a switchgear cabinet housing in which a plurality of electrical and electronic components and devices are arranged. A plurality of input/output modules are located in the upper portion of the switchgear cabinet housing, a plurality of fuse elements and a larger number of circuit breakers are located in the middle portion, and clamping devices for securing cable harnesses leading to individual machines are located in the lower portion. To connect the individual components and devices to each other, several terminals for access wiring, several terminals for intermediate routing and several terminals for outgoing routing are arranged in the switchgear cabinet.

### SUMMARY

This section provides a general summary of the disclosure, and is not a comprehensive disclosure of its full scope or all of its features.

It is one aspect of the invention to provide a switchgear cabinet configuration system for configuring a switchgear cabinet, in which the layout can be designed in a way that is efficient for the user with a good balance of possible optimization aspects.

A first aspect relates to a computer-aided switchgear cabinet configuration system, set up for configuring a switchgear cabinet, which has a modular switchgear cabinet equipment, which is composed of a plurality of electrical and/or electronic built-in modules and further optional components in an application-specific manner. The computer-aided switchgear cabinet configuration system has a computing unit which comprises a classification device and an evaluation and simulation unit. Furthermore, a database is provided, which may also be a cloud storage. The classification device is arranged to identify one or more switchgear cabinet configurations for a plant to be controlled, taking into account a framework condition data set, by selecting suitable configurations from a historical stock data set stored in the database. In particular, these stored configurations comprise configurations of switchgear cabinets which have already been produced, i.e. which are successfully in use. The evaluation and simulation unit is adapted to adapt the switchgear cabinet configurations identified taking into account the framework condition data set within a parameter space spanned by different parameters, so that a bundle of different switchgear cabinet concepts is generated, each with different (three-dimensional) layouts.

The evaluation and simulation unit can be set up to calculate and graphically output deviations from the framework conditions defined in the framework conditions data set and, if applicable, the resulting objectives for each switchgear cabinet concept of the bundle.

The framework condition data set may in particular comprise a desired specification of the switchgear cabinet. The objectives may in particular comprise a manufacturing time and/or the manufacturing cost of the switchgear cabinet.

The enclosure configuration system may further be configured to create the framework condition record using a first electronic selection form by interaction with a user.

According to one embodiment, there is further provided a pattern recognition unit that uses the classification device to identify the one or more switchgear cabinet configurations using pattern recognition.

For this purpose, the pattern recognition unit may use fuzzy logic, artificial intelligence or neural networks for pattern recognition.

According to a further embodiment, the evaluation and simulation unit is arranged to generate the parameters of the parameter space by means of a second electronic selection form. This can also be generated or completed by interaction with a user.

According to another embodiment, the parameters spanning the parameter space include depth of manufacturing, space requirements, and/or cost of the switchgear cabinet.

According to a further embodiment, a decision device is provided, arranged for selecting a switchgear cabinet concept from the bundle of different switchgear cabinet concepts. This decision device can be set up to accept user inputs. It may also be set up to be completely automated, so that the computer-aided cabinet configuration system makes the selection independently. This selection can take into account a quality function described further below.

According to a further embodiment, the system is arranged to store the switchgear cabinet configuration of the selected switchgear cabinet concept in the database, so that the system can refer back to it in a future switchgear cabinet configuration.

Such conceptual design and construction of enclosure equipment is created software-based, for example by EPLAN Pro Panel® in the form of a CAD-supported design. The planned design includes, in particular, the three-dimensional mounting structure in the form of a layout, virtual wiring of the electrical and electronic built-in modules and, if necessary, other components, and a configuration of copper busbars and the like for flexible power distribution systems matched to the enclosure equipment. The electrical or electronic installation modules can, for example, be fixed in the switchgear cabinet housing using top-hat rails. Optional components, such as fans, ventilators, filters, heat exchangers, air conditioning units, interior lighting systems, cable entries and the like can also be designed to complete the switchgear cabinet.

The software-supported design carried out to create the three-dimensional layout is characterised by a classification device and an evaluation and simulation unit which, in accessing an installation module library (database) connected to it, supports the layout of the switchgear cabinet equipment, taking into account the structural boundary conditions, for example distance dimensions, accessibility or electrical energy consumption specifications.

Various installation modules can be mounted on a common mounting rail in the switchgear cabinet housing. The switchgear cabinet is designed to be function block-oriented, which means that only those built-in modules are included that are necessary for the function of a machine. In addition, the switchgear cabinet housing also contains several bus terminals for connecting the switchgear cabinet to a bus system, a signal monitoring unit, several input/output modules, a power supply unit and load relays. In the bottom of the switchgear cabinet housing, there are cable bushings through which the connection lines for machines as well as lines for additional sensors and/or actuators can be led into the interior of the switchgear cabinet. This switchgear cabinet of the second embodiment is designed in such a way that it corresponds at least to protection class IP65.

As a rule, the layout of switchgear cabinets must meet framework conditions defined by the application and can also be optimized according to additional aspects, for example with regard to thermal load capacity, electromagnetic compatibility, packing density of built-in modules and other components, electrical energy consumption and the like. However, these optimization aspects are usually in a competing relationship with each other, so that optimization in the direction of one aspect is at the expense of another aspect. For example, increasing the packing density usually leads to a higher thermal load on the switchgear cabinet.

Embodiments include the technical teaching that the configuration of a switchgear cabinet initially starts from the creation or provision of a functional planning of the switchgear cabinet equipment in the form of an electrical circuit diagram SP. Subsequently, the electrical circuit diagram SP of the enclosure equipment is converted into a three-dimensional layout L1 for the arrangement of at least several electrical and/or electronic installation modules in at least one enclosure housing, wherein the three-dimensional layout L1 of the enclosure equipment is created by a software layout assistance unit LA—for example the product EPLAN Pro Panel® of the applicant—in access to an installation module library connected thereto.

It may be provided that subsequently a modification of the three-dimensional layout L1 created in this way is performed by a modification algorithm Mod implemented in the layout assistance unit LA for generating at least one alternative three-dimensional layout L2. Thereby, the modification algorithm Mod for modifying the three-dimensional layout L1 into the alternative layout L2 determines values of a quality function and optimizes the modification in such a way that the quality function assumes an extremum. Subsequently, the switchgear cabinet can be transferred to the assembly workshop according to the alternative three-dimensional layout L2.

The modification algorithm makes use of the mathematical quality function. The quality function embodies the goal that is to be achieved with the modification, for example an increase in the space utilization factor, i.e. the packing density. If several goals are to be achieved at the same time, this mathematical model provides the prerequisite for finding compromises in the sense of a lowest common denominator in the case of conflicting goals. In addition to the quality function, hard boundary conditions can also be specified, such as a maximum temperature or a maximum energy consumption. For each layout variant an evaluation can take place in several runs, which are tested with the quality function. To find the next variant, any optimization method can be used, which derives a new variant with a presumably improved value of the quality function from the history of the previous variants.

In other words, a three-dimensional layout L1 is first created by the designer in implementation of the electrical schematic SP using the software layout assistance. Subsequently, it may be specified that the three-dimensional layout, which is arranged in a distributed manner on, for example, two switchgear cabinets, according to the original layout L1, should fit on a smaller mounting area of a single switchgear cabinet. According to this specification, the modification algorithm Mod generates a correspondingly adapted proposal for a modified layout L2, possibly disregarding normally applicable spacing dimensions or the like. In this case, however, since a higher degree of space utilization has priority over predetermined distance dimensions, preference is given to the modified layout L2. Any higher heat generation resulting from this can then be compensated for, for example, by installing a cooling device with a higher cooling capacity.

If a pre-certification of the alternative three-dimensional layout L2 shows that this embodiment is permissible, it can be provided that this alternative three-dimensional layout L2 is stored in the application database A connected to the layout assistance unit LA in order to take it into account as an originally permissible layout in future conversions of identical or similar electrical circuit diagrams SP′. This measure results in an enrichment of the application database A, which in this respect is not limited solely to embodiments in which predetermined structural boundary conditions and the like are rigidly observed. Due to this flexibility, a more application-oriented layout of switchgear cabinet equipment is possible. Thus, the solution according to the invention creates a method which takes into account individual optimization possibilities including their interaction with each other when creating a layout for a switchgear cabinet.

In terms of system technology, this solution can be implemented by an additional implementation or assignment of the Mod modification algorithm in the LA layout assistance unit, which can be a computer with EPLAN Pro Panel® software installed on it.

For example, the modification algorithm Mod has a parameterizable quality function that includes at least one changeable layout optimization parameter P1 to Pn. This layout optimization parameter provides the planner with an input option—for example, by means of a rotary control simulated on a graphical user interface—for different optimization directions in order to select desired weightings for a layout modification. Based on the modification algorithm Mod, the system determines a coordinated, reasonable ratio of various predetermined layout optimization parameters and proposes an associated alternative layout L2. In the simplest case, however, it is also conceivable that only a single layout optimization parameter can be predefined. Various layout optimization parameters P1 to Pn are conceivable, of which a non-limiting selection is given below:

A first layout optimization parameter P1 describes the degree of space utilization of the available switchgear cabinet volume in relation to the geometric dimensions of the electrical and/or electronic installation modules to be installed therein.

A second layout optimization parameter P2 describes a thermal load level taking into account the waste heat generated by the built-in modules, the ambient heat of the switchgear cabinet and, if applicable, the heat dissipation capacity of an optional fan/air conditioning unit.

A third layout optimization parameter P3 describes the electrical power consumption level taking into account at least the electrical power consumption of all built-in modules. Although the total electrical power depends on the electrical design of the switchgear cabinet equipment, alternative built-in modules could be considered that differ in power consumption for the same function. Therefore, optimisation can also be carried out in this respect.

A fourth layout optimization parameter P4 describes a degree of EMC (EMC=electromagnetic compatibility), which takes into account the electromagnetic emission of the built-in modules.

A fifth layout optimization parameter P5 describes the wiring length degree in order to take into account specifications regarding minimum or maximum cable lengths when arranging built-in modules in the switchgear cabinet housing.

Since some of these layout optimization parameters P1 to P5, which are only given here as examples, are in competition with each other, i.e. the optimization with respect to one parameter can be at the expense of another parameter, the mathematical methodology of the parameterizable quality function enables the best possible balance between different optimization parameters in order to find a compromise in this respect. In the process, a higher priority can be given to one parameter than to another parameter in the sense of prioritization. With the aid of the modification algorithm Mod according to the invention, it is thus possible to optimize the switchgear cabinet equipment with respect to different criteria relating to space utilization, thermal load, electrical energy consumption, EMC, material costs for wiring and the like.

A further aspect relates to a cabinet manufacturing system arranged to manufacture a cabinet, comprising a computer-aided cabinet configuration system as described above and below, and an at least partially automated, or fully automated, manufacturing line arranged to at least partially automated, or fully automated, assemble the cabinet in accordance with a cabinet concept generated by the cabinet configuration system.

Another aspect relates to the use of a computer-aided switchgear cabinet configuration system described above and below for fully automated manufacturing of a switchgear cabinet.

A further aspect relates to a method for configuring a switchgear cabinet comprising modular switchgear cabinet equipment that is composed, in an application-specific manner, of a plurality of electrical and/or electronic built-in modules and further optional components. In the method, one or more switchgear cabinet configurations for a system to be controlled are identified, taking into account a framework condition data set, by selecting suitable configurations from a historical stock data set stored in a database. Thereupon, an adaptation of the switchgear cabinet configurations identified under consideration of the framework condition data set takes place within a parameter space spanned by different parameters, so that a bundling of different switchgear cabinet concepts with respectively different layouts is generated. Thereupon, one of the switchgear cabinet concepts with a certain layout is selected from the bundle of different switchgear cabinet concepts, whereupon the switchgear cabinet is manufactured according to this selected switchgear cabinet concept.

A final aspect relates to a computer program product having program code means for performing the method, when the computer program product runs on a computing unit of a control panel manufacturing system or is stored on a computer-readable medium or in cloud storage.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further embodiments are shown in more detail below with reference to the figures. Therein:

FIG. 1 shows a schematic representation of a computer-aided switchgear cabinet configuration system for configuring a switchgear cabinet;

FIG. 2 shows a schematic representation of a switchgear cabinet manufacturing system;

FIG. 3 shows a flow diagram of the process performed by the system for the optimizable configuration of a switchgear cabinet;

FIG. 4 shows a more detailed schematic representation of a computer-aided switchgear cabinet configuration system for configuring a switchgear cabinet.

### DETAILED DESCRIPTION

Example embodiments will now be described more fully with reference to the accompanying drawings.

FIG. 1 shows a schematic representation of a computer-aided switchgear cabinet configuration system 1 for configuring a switchgear cabinet. The switchgear cabinet configuration system 1, hereinafter also referred to as “configuration tool”, comprises as essential components a classification device 10 and an evaluation unit/simulation unit 18.

By means of the switchgear cabinet configuration system 1, a switchgear cabinet concept 100 for a plant to be controlled is created from framework conditions 2, which comprise a desired specification of the switchgear cabinet, for example a desired functionality or a control task, and the objectives resulting therefrom, which describe the economic parameters of the project, for example the costs or the throughput times. In doing so, the switchgear cabinet concept 100 of a concretely executable configuration with the resulting objectives is described, so that there is no longer any need to further detail or interpret the information output by the switchgear cabinet configuration system, e.g. the selection of components from different manufacturers.

The framework condition data set 2 is configured, for example, by means of a first electronic selection form, wherein the information necessary for describing the framework conditions is stored in a database partition 11, for example, about the system to be controlled (energy consumption, location of use, etc.), about the environmental conditions (temperature, etc.), about the geometrical parameters (size/arrangement of the air-conditioning unit, etc.), component preferences (manufacturer/design).

The framework condition data set 2, which generally comprises a number of individual data, is transferred to a classification device 10. The classification device 10 determines from the framework conditions by means of a pattern recognition unit 20 at least one switchgear cabinet configuration 30 with the framework conditions anchored in the framework condition data set 2, by selecting suitable concepts/configurations from a stored, historical stock. These concepts are stored in a database (partition) 12.

The pattern recognition unit 20 makes use of pattern recognition and/or fuzzy logic and/or neural network technologies and methods.

The switchgear cabinet configuration 30 identified in this way is adapted by means of the evaluation unit/simulation unit 18 within a parameter space spanned by different parameters. These different parameter sets are stored in a database (partition) 13. For example, the parameter space contains parameter sets relating to the different manufacturing variants, in particular information on the automation depth of the manufacturing variants and the resulting effects on the framework conditions, such as space requirements and the effects on the objectives, as well as higher-level changeable objectives, such as the maximum cost budget. The individual parameters of the parameter sets are selected, for example, by means of a second electronic selection form. The evaluation unit/simulation unit 18 simulates, for example by numerical simulation, a bundle of switchgear cabinet concepts 100 based on at least one switchgear cabinet configuration 30 defined by the framework conditions 2 and the parameter space defined by the selected parameter sets.

The evaluation unit/simulation unit 18 may be arranged to calculate and graphically output the deviations from the required framework conditions of the framework conditions data set 2 and the objectives for each switchgear cabinet concept of the bundle. The selection of the switchgear cabinet configuration to be manufactured is made by means of the decision device 40.

The design and production of switchgear cabinets is an extremely complex matter, which can be broken down into different dimensions.

### Dimension of the Value Chain:

The design/production of switchgear cabinets can be divided into several value creation stages (engineering, work preparation, order planning and implementation), whereby each of these value creation stages has a large number of degrees of freedom and is usually provided by several participants in the ecosystem.

### Lot Size Dimension:

Each switchgear cabinet can be considered as a unique piece, since for each set of conditions and objectives a variety of planning options are possible in the engineering, these can differ e.g. in the form of the electrical design or the component selection.

Once the switchgear cabinet is configured, it can be manufactured in different ways, e.g. different automation depths. The manufacturing variant has a direct impact on the engineering phase, e.g. automatic assembly limits the packing density.

### Framework Dimension:

Framework conditions are understood to be specifications, e.g. of a geometric nature, preferred components of different manufacturers or the functional scope, of the customer. These framework conditions can lead to the fact that, for example, certain production variants are not feasible.

### Dimension of the Objectives:

Objectives can be understood as business parameters (preferences), these describe the dominant aspects that influence individual decisions across all stages of the value chain.

### Dimension of the Production Variants:

Different manufacturing partners have different manufacturing infrastructures, which are essentially differentiated by different levels of automation (see Lot Size Manufacturing Variants).

The switchgear cabinet configuration system, which provides information across all value-added stages and, if necessary, allows access to past projects, can significantly reduce the planning effort and identify optimization approaches.

The customer benefits addressed here are largely dependent on the content of the optimization approaches to be determined. In general, the following customer benefits are served:
1) Ease of Use: The system suggests different switchgear cabinet configurations for each stage of the value chain, depending on the situation, and displays the respective consequences for the downstream steps, e.g. feasibility of automatic wiring.
2) Planning reliability: By linking business parameters, e.g. costs or resources, the profitability of the overall project can be simulated, for example.
3) Flexibility: Based on the engineering results, the way of implementation can be simulated individually in each stage of the value chain.

A switchgear cabinet configuration system is provided, which makes it possible to propose an ideal configuration of a switchgear cabinet depending on several parameters, whereby the system:

has a database with different partitions,

where in a partition the general conditions (customer specifications),

in a partition the objectives (preferences),

in a partition, the production variants (preferences),

already implemented configurations are stored in a partition;

had linking provisions that linked the framework conditions to the objectives in an appropriate way;

has linking rules that link the configuration to different production variants;

has a pattern recognition unit which recognizes similar known configurations for predefined framework conditions and objectives in a predefinable deviation interval and outputs configuration suggestions;

has a simulation unit, which simulates possible (virtual) production variants, electrical constructions for different configurations;

has an evaluation unit which evaluates the results of the respective simulations in relation to the various objectives and presents the result and is adaptable in the respective value creation stages, e.g. adaptation of the proposed manufacturing variant to the real manufacturing infrastructure.

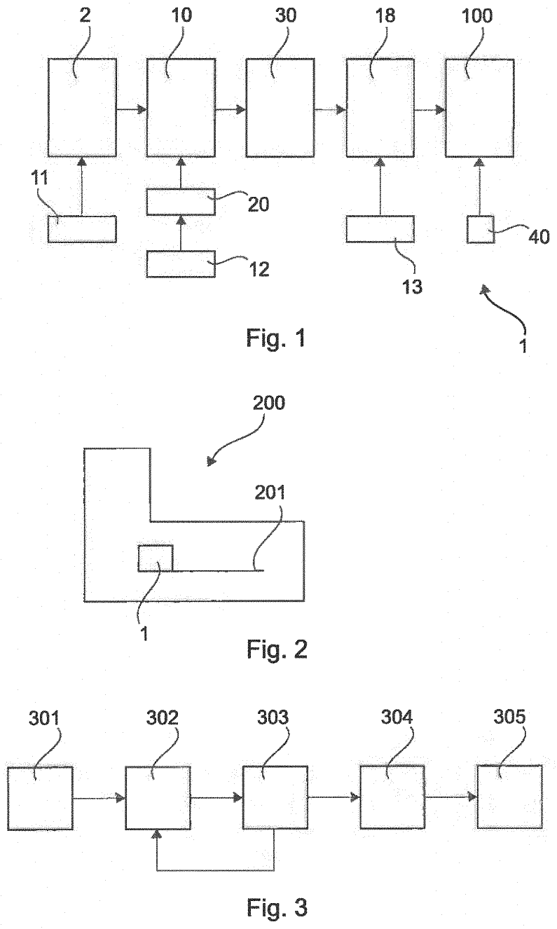

FIG. 2 shows a switchgear cabinet manufacturing system 200 comprising a switchgear cabinet configuration system 1 described above, which is connected to the fully or partially automated manufacturing line 201 and thus controls the robots of the manufacturing line.

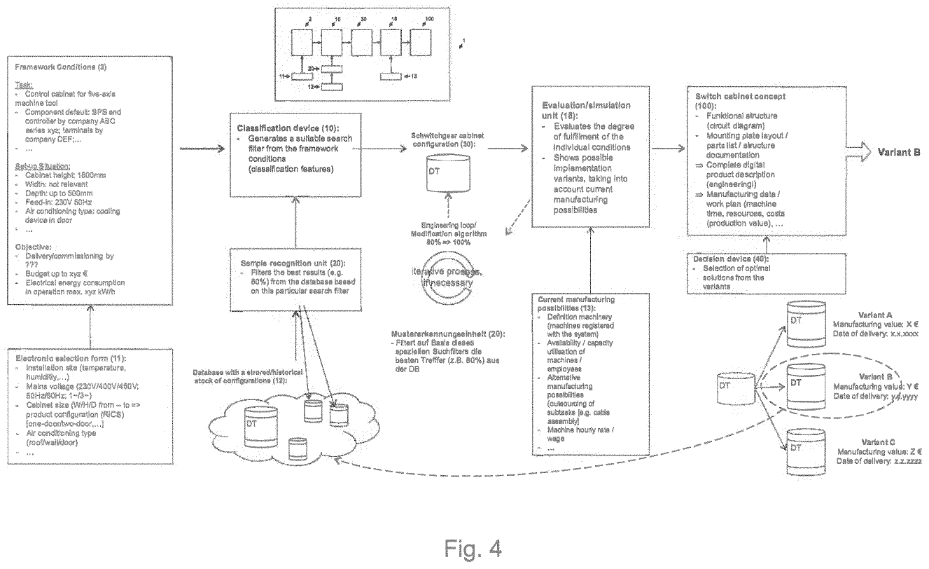

FIG. 3 shows a flow diagram of a method for configuring a switchgear cabinet, in which in step 301, as described further above, one or more switchgear cabinet configurations are identified, in step 302, as described above, a bundle of different switchgear cabinet concepts is generated, in step 303 a selection of a switchgear cabinet concept with a layout for a switchgear cabinet to be manufactured is selected from the bundle of different switchgear cabinet concepts. If the system determines that the selected switchgear cabinet concept does not meet the predetermined requirements, it may be returned to the evaluation and simulation unit, which then generates a new bundle of switchgear cabinet concepts therefrom, taking into account any changed parameters. This control loop may be run several times until the switchgear cabinet concept is optimized. In step 304, the switchgear cabinet is then manufactured according to the selected final switchgear cabinet concept. In step 305, the selected switchgear cabinet concept (see also dashed lower arrow in FIG. 4) is stored in the database 12 for later use by the classification device. In particular, the system may thus be structured as a self-learning system that continuously increases its “knowledge”. In particular, the circuit diagram configurations stored in the database 12 can be used to create switchgear cabinet concepts for future customers which are characterized, for example, by low material and tooling usage, low weight, low energy consumption, low heat generation and small dimensions.

FIG. 4 is a more detailed schematic representation of a computer-aided switchgear cabinet configuration system for configuring a switchgear cabinet.

Supplementally, it should be noted that “including” and “comprising” do not exclude other elements or steps, and the indefinite articles “a” or “an” do not exclude a plurality. It should further be noted that features or steps that have been described with reference to any of the above embodiments may also be used in combination with other features or steps of other embodiments described above. Reference signs in the claims are not to be regarded as limitations.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A computer-aided switchgear cabinet configuration system, adapted to configure a switchgear cabinet which comprises a modular switchgear cabinet equipment which is composed, in an application-specific manner, of a plurality of electrical and/or electronic installation modules and further optional components, including:
a computing unit with a classification device;
a database;
wherein the classification device is adapted to identify one or more switchgear cabinet configurations for a plant to be regulated, taking into account a framework condition data set, by selecting suitable configurations from a historical stock data set stored in the database;
wherein an evaluation and simulation unit is adapted to adapt the switchgear cabinet configurations identified taking into account the framework condition data set within a parameter space spanned by different parameters, which comprise manufacturing depth and space requirement, so that a bundle of different switchgear cabinet concepts with different layouts in each case is generated,
wherein a decision device is adapted to select a switch cabinet concept from the bundle of different switch cabinet concepts by user input or automated selection via the user or autonomously, respectively.

2. The computer-aided switchgear cabinet configuration system according to claim 1, wherein the evaluation and simulation unit is adapted to calculate and graphically output deviations from the framework conditions defined in the framework condition data set and, if applicable, the objectives resulting therefrom for each switchgear cabinet concept of the bundle, wherein the objectives comprise a manufacturing time of the switchgear cabinet.

3. The computer-aided switchgear cabinet configuration system according to claim 1, wherein the framework condition data set comprises a desired specification of the switchgear cabinet.

4. (canceled)

5. The computer-aided switchgear cabinet configuration system according to claim 1, wherein the switchgear cabinet configuration system is arranged to generate the framework condition data set by means of a first electronic selection form.

6. The computer-aided switchgear cabinet configuration system according to claim 1, further comprising:
a pattern recognition unit which uses the classification device to identify the one or more switchgear cabinet configurations by means of pattern recognition.

7. The computer-aided switchgear cabinet configuration system according to claim 6, wherein the pattern recognition unit uses fuzzy logic, artificial intelligence or neural networks for pattern recognition.

8. The computer-aided switchgear cabinet configuration system according to claim 1, wherein the evaluation and simulation unit is arranged to generate the parameters of the parameter space by means of a second electronic selection form.

9-10. (canceled)

11. The computer-aided switchgear cabinet configuration system according to claim 1, adapted to store the switchgear cabinet configuration of the selected switchgear cabinet concept in the database.

12. The computer-aided switchgear cabinet configuration system according to claim 1, wherein the evaluation and simulation unit comprises a modification algorithm implemented therein or associated therewith for generating at least one alternative switchgear cabinet concept, wherein the modification algorithm for modifying the switchgear cabinet concept into the alternative switchgear cabinet concept determines values of a quality function and optimizes the modification in such a way that the quality function assumes an extremum, wherein the transformation algorithm includes a parameterizable quality function having at least one predetermined layout optimization parameter of a layout optimization parameter set.

13. (canceled)

14. The computer-aided switchgear cabinet configuration system according to claim 12, wherein the layout optimization parameter set comprises a space utilization factor of the available switchgear cabinet volume in relation to geometric dimensions of the electrical and/or electronic installation modules to be installed therein.

15. The computer-aided switchgear cabinet configuration system according to claim 12, wherein the layout optimization parameter set comprises a thermal load factor taking into account the waste heat generated by the built-in modules, the ambient heat of the switchgear cabinet housing and the heat dissipation capacity of an optional fan/air conditioning unit.

16. The computer-aided switchgear cabinet configuration system according to claim 12, wherein the layout optimization parameter set comprises an electrical power consumption level taking into account at least the electrical power consumption of the built-in modules.

17. The computer-aided switchgear cabinet configuration system according to claim 12, wherein the layout optimization parameter set comprises an EMC degree which takes into account the electromagnetic emission of the built-in modules.

18. The computer-aided switchgear cabinet configuration system according to claim 12, wherein the layout optimization parameter set comprises a wiring length degree in order to take into account specifications regarding minimum or maximum cable lengths when arranging the built-in modules in the switchgear cabinet housing.

19. A switchgear cabinet manufacturing system, adapted to manufacture a switchgear cabinet, comprising:
a computer-aided switchgear cabinet configuration system according to claim 1; and
an at least partially automated production line, set up for at least partially automated assembly of the switchgear cabinet in accordance with a switchgear cabinet concept generated by the switchgear cabinet configuration system.

20. The use of a computer-aided switchgear cabinet configuration system according to claim 1 for fully automated production of a switchgear cabinet.

21. A computer-implemented method for configuring a switchgear cabinet which comprises a modular switchgear cabinet equipment which is assembled in an application-specific manner from a plurality of electrical and/or electronic built-in modules and further optional components, having the steps:
Identifying, taking into account a framework condition data set, one or more switchgear cabinet configurations for a plant to be controlled by selecting suitable configurations from a historical stock data set stored in a database;
Adapting the switchgear cabinet configurations identified in consideration of the framework condition data set within a parameter space spanned by different parameters, which comprise manufacturing depth and space requirement, so that a bundle of different switchgear cabinet configurations each with different layouts is generated;
via user input or automated selection of a control cabinet concept with a layout via the user or independently, from the bundle of different switchgear cabinet concepts.

22. A computer program product having program code means for performing the method of claim 21, when the computer program product runs on a computing unit of a switchgear cabinet manufacturing system.
